(19) United States
(12) Patent Application Publication
(10) Pub. No.: US 2024/0304454 A1
(43) Pub. Date: Sep. 12, 2024

(54) MANUFACTURING METHOD OF SEMICONDUCTOR DEVICE

(71) Applicant: SK hynix Inc., Icheon-si (KR)

(72) Inventor: Pil Hoon JUNG, Icheon-si (KR)

(21) Appl. No.: 18/333,000

(22) Filed: Jun. 12, 2023

(30) Foreign Application Priority Data
Mar. 9, 2023 (KR) 10-2023-0030876

(51) Int. Cl. H01L 21/311; H01L 21/033

(52) U.S. Cl. CPC H01L 21/31144; H01L 21/0337

(57) ABSTRACT

A manufacturing method of a semiconductor device may include: forming a stack including first material layers and second material layers that are alternately stacked; forming, on the stack, an inorganic material-containing polymer mask including a first stepped structure; and forming a second stepped structure in the stack by etching the stack using the polymer mask as an etching barrier.

### CROSS-REFERENCE TO RELATED APPLICATION

This application claims priority under 35 U.S.C. § 119 to Korean Patent Application No. 10-2023-0030876 filed in the Korean Intellectual Property Office on Mar. 9, 2023, which is incorporated herein by reference in its entirety.

### BACKGROUND

### 1. Technical Field

Embodiments of the present disclosure relate to an electronic device, and more particularly, to a semiconductor device and a manufacturing method of the semiconductor device.

### 2. Related Art

The degree of integration of a semiconductor device is mainly determined by an area occupied by a unit memory cell. Recently, as improvements in the degree of integration of a semiconductor device for forming memory cells in a single layer on a substrate reaches its limits, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a manufacturing method of a semiconductor device may include: forming a stack including first material layers and second material layers that are alternately stacked; forming, on the stack, an inorganic material-containing polymer mask including a first stepped structure; and forming a second stepped structure in the stack by etching the stack using the polymer mask as an etching barrier.

In an embodiment, a manufacturing method of a semiconductor device may include: forming a stack; applying, on the stack, resist including monomers and inorganic nanoparticles; pressing the resist with a polymer mold including a reversed target structure; forming an inorganic material-containing polymer mask including a first target structure by polymerizing the monomers and the inorganic nanoparticles in the resist; removing the polymer mold; and etching the polymer mask and the stack to form a second target structure in the stack, wherein the first target structure is substantially reproduced to form the second target structure in the stack.

### BRIEF DESCRIPTION OF THE DRAWINGS

FIG. 1A to FIG. 1D are diagrams describing a manufacturing method of a semiconductor device in accordance with an embodiment of the disclosure.

FIG. 2 is a diagram describing a manufacturing method of a semiconductor device in accordance with an embodiment of the disclosure.

FIGS. 3A to 3D are diagrams illustrating a manufacturing method of a semiconductor device in accordance with an embodiment of the disclosure.

FIGS. 4A to 4D are diagrams illustrating a manufacturing method of a semiconductor device in accordance with an embodiment of the disclosure.

FIGS. 5A to 5F are diagrams illustrating a manufacturing method of a semiconductor device in accordance with an embodiment of the disclosure.

### DETAILED DESCRIPTION

Various embodiments are directed to a semiconductor device having a stable structure and improved characteristics and to a method of manufacturing the semiconductor device.

By stacking memory cells in three dimensions, it is possible to improve the degree of integration of a semiconductor device. It is also possible to provide a semiconductor device having a stable structure and improved reliability.

Hereafter, embodiments in accordance with the technical spirit of the present disclosure will be described with reference to the accompanying drawings.

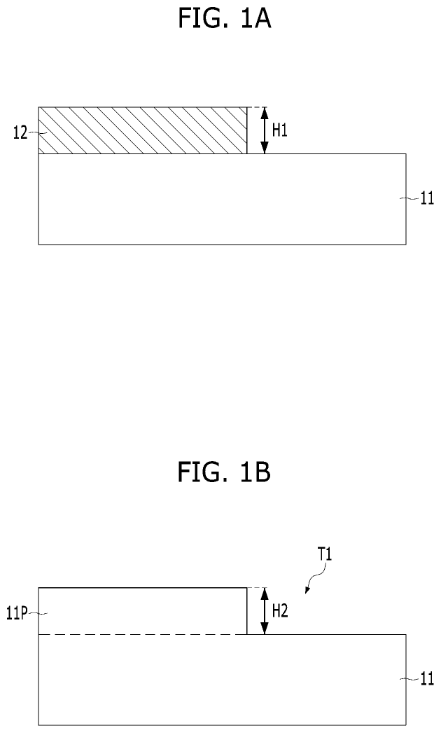

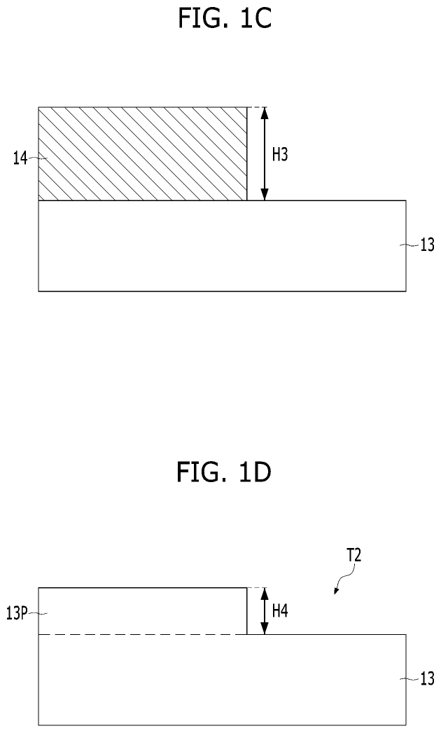

FIGS. 1A to 1D are diagrams for describing a manufacturing method of a semiconductor device in accordance with an embodiment of the disclosure.

Referring to FIGS. 1A and 1B, a first polymer mask 12 containing an inorganic material may be formed on a first target layer 11. The first target layer 11 may be a single layer or multilayered. As an example, the first target layer 11 may include first material layers and second material layers that are alternately stacked. Subsequently, the first target layer 11 may be etched using the first polymer mask 12 as an etching barrier to form a first trench T1. When the first target layer 11 is etched, the first polymer mask 12 may be used as a hard mask. The first polymer mask 12 may have a lower etching rate than the first target layer 11.

As an example, the first polymer mask 12 may include a polymer formed by polymerizing monomers and inorganic nanoparticles. The polymer may be a compound having at least one acryloyl group or methacryloyl group, and may be a (meth) acrylic compound. The inorganic nanoparticle may include at least one of TiO₂, Al₂O₃, ZrO₂, Cr₂O₃, WO₃, ZnO, SnO₂, and Fe₂O₃. The monomer may include dipentaerythritol penta/hexaacrylate (DPHA). The first polymer mask 12 may include a mask material for dry etching.

In the process of etching the first target layer 11, the first polymer mask 12 may also be etched. The first polymer mask 12 may be etched when the first target layer 11 is etched. In addition, the shape of the first polymer mask 12 may be transferred to the first target layer 11. For example, a first pattern 11P that reflects the shape of the first polymer mask 12 may be defined in the first target layer 11 by the first trench T1. The first polymer mask 12 may have a first height H1, and the first pattern 11P may have a second height H2.

The etching selectivity of the first polymer mask 12 and the first target layer 11 may be adjusted in accordance with a target first height H1. For example, when the first height H1 of the first polymer mask 12 is increased, an etching depth of the first target layer 11 may be increased and the second height H2 may be increased. In another example, when the first height H1 of the first polymer mask 12 is reduced, the etching depth of the first target layer 11 may be reduced and the second height H2 may be reduced. The first height H1 may be determined in consideration of etching rates of the first polymer mask 12 and the first target layer 11, a target height of the first pattern 11P, and the like. When the first polymer mask 12 and the first target layer 11 have an etching rate of about 1:1, the first polymer mask 12 may be formed so that the rate at which the first height H1 and the second height H2 are formed is also about 1:1.

As an example, the etching selectivity of the first polymer mask 12 and the first target layer 11 may be adjusted according to the type or the content of the inorganic material contained in the first polymer mask 12. The etching rate of the first polymer mask 12 having a higher inorganic content may be lower than that of the first polymer mask 12 having a lower inorganic content. When the inorganic content is high, the polymer mask may have properties closer to pure inorganic materials.

The hardness of the first polymer mask 12 may vary depending on the type of inorganic material included in the first polymer mask 12. As an example, the first polymer mask 12 may include metal such as chromium (CR) or tungsten (W), and may have greater hardness than a polymer mask including no metal. The etching rate of the first polymer mask 12 including metal may be lower than that when using a first polymer mask 12 that does not include metal.

Referring to FIGS. 1C and 1D, a second polymer mask 14 containing an inorganic material may be formed on a second target layer 13. Subsequently, the second target layer 13 may be etched using the second polymer mask 14 as an etching barrier to form a second trench T2. As an example, the second polymer mask 14 may include a polymer formed by polymerizing monomers and inorganic nanoparticles. The etching selectivity of the second polymer mask 14 and the second target layer 13 may be changed according to the type or the content of the inorganic material contained in the second polymer mask 14. The etching selectivity of the second polymer mask 14 and the second target layer 13 may be selected in accordance with the height H3 of the second polymer mask 14.

A second pattern 13P may be defined in the second target layer 13 by the second trench T2. The second pattern 13P may have a shape similar to that of the second polymer mask 14. The second polymer mask 14 may have a third height H3 and the second pattern 13P may have a fourth height H4. The third height H3 may be determined in consideration of etching rates of the second polymer mask 14 and the second target layer 13, a target height of the second pattern 13P, and the like. When the etching rate of the second polymer mask 14 is greater than that of the second target layer 13, the second polymer mask 14 may be formed so that the third height H3 is greater than the fourth height H4.

Referring to FIGS. 1A to 1D, the etching selectivity between the target layers 11 and 13 and the polymer masks 12 and 14 may be adjusted by changing the composition of the polymer masks 12 and 14 according to the materials of the target layers 11 and 13. Alternatively, the etching selectivity between the target layers 11 and 13 and the polymer masks 12 and 14 may be adjusted by changing the heights H1 and H3 of the polymer masks 12 and 14 according to the material of the target layers 11 and 13.

As an example, the first target layer 11 may include silicon oxide such as SiO₂ and the second target layer 13 may include silicon nitride such as Si₃N₄. The etching rate of the second target layer 13 may be lower than that of the first target layer 11. Accordingly, in order to form the first pattern 11P and the second pattern 13P to have substantially the same height (i.e., H2=H4), the composition or heights H1 and H3 of the first polymer mask 12 and the second polymer mask 14 may be adjusted.

For example, the first polymer mask 12 and the second polymer mask 14 may have different compositions. The inorganic content in the second polymer mask 14 may be higher than that in the first polymer mask 12. Inorganic nanoparticles having a size of several nanometers may be aggregated to have properties close to pure inorganic materials, and the height of a mask may be increased as the inorganic content increases. As an example, the content of metal included in the second polymer mask 13 may be higher than that of metal included in the first polymer mask 12.

For another example, the height H1 of the first polymer mask 12 and the height H3 of the second polymer mask 14 may be different from each other. The second polymer mask 14 may be formed to be thicker than the first polymer mask 12, and the third height H3 may be greater than the first height H1. By increasing the height H3 of the second polymer mask 14, the second pattern 13P having substantially the same height H4 as the height H2 of the first pattern 11P may be formed.

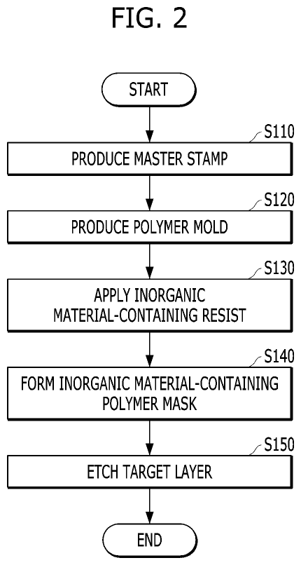

FIG. 2 is a diagram for describing a manufacturing method of a semiconductor device in accordance with an embodiment of the disclosure. Hereinafter, a description overlapping with the previously described content will be omitted.

First, a master stamp may be produced (S110). The master stamp may be formed to include a target structure to be implemented in a target layer. The target structure may be a three-dimensional structure such as a stepped shape. As an example, the master stamp may be formed by etching a substrate such as a silicon wafer. After photoresist is applied on the substrate, a photoresist pattern may be formed by a lithography method. Subsequently, the master stamp may be manufactured by etching the substrate using the photoresist pattern as an etching barrier.

Subsequently, a polymer mold may be produced using the master stamp (S120). The polymer mold may include a reversed target structure. The polymer mold may include a polymer material such as polydimethylsiloxane (PDMS). A plurality of polymer molds may be duplicated using the master stamp. Surface energy may be reduced by performing surface treatment on the master stamp. As a result, the surface of the master stamp may have hydrophobicity, and the polymer mold may be easily separated from the master stamp. Hundreds or more polymer molds may be manufactured using one master stamp.

Subsequently, inorganic material-containing resist may be applied on the target layer (S130). The target layer may be a stack. The inorganic material-containing resist may be obtained by dispersing inorganic nanoparticles in a monomer dispersion solution. As an example, the inorganic-containing resist may include monomers and inorganic nanoparticles, and may further include a solvent such as ethanol, an initiator, and the like. The initiator may be a polymerization initiator that generates radicals by light such as infrared rays, visible rays, ultraviolet rays, far ultraviolet rays, X-rays, and electron beams.

Subsequently, an inorganic material-containing polymer mask may be formed (S140). As an example, a polymer mask may be formed by a nanoimprint lithography method. The inorganic material-containing resist may be pressed with the polymer mold manufactured using the master stamp. The resulting inorganic material-containing resist may be formed to include a first target structure. Subsequently, after the pressed inorganic material-containing resist is cured, the polymer mold may be removed. The curing process may be performed using heat or ultraviolet (UV) light. A polymerization reaction may be induced between the monomers and the inorganic nanoparticles in the resist by the curing process, so that a polymer may be formed. As a result, the inorganic material-containing polymer mask having the first target structure with a thickness of several nanometers may be formed.

Subsequently, the target layer may be etched using the inorganic material-containing polymer mask as an etching barrier (S150). In the etching process, the inorganic material-containing polymer mask may be etched, and the shape of the inorganic material-containing polymer mask may be transferred into or reflected in the target layer. As an example, by etching the inorganic material-containing polymer mask and the target layer, a second target structure in which the first target structure is substantially reproduced in the target layer may be formed. A first height of the first target structure and a second height of the second target structure may be identical to each other or different from each other, and a first width of the first target structure and a second width of the second target structure may be substantially identical to each other. The first height may be adjusted in consideration of etching rates of the inorganic material-containing polymer mask and the target layer.

According to the manufacturing methods described above, a plurality of polymer molds may be manufactured using a master stamp. An inorganic material-containing polymer mask including a target structure having a nano size or thickness may be formed by a nano-imprint method. A three-dimensional target structure may be formed in a target layer by using one inorganic material-containing polymer mask. Various target structures such as a stepped structure and a reversed pyramid structure may be formed in the target layer with only a single etching process using the inorganic material-containing polymer mask.

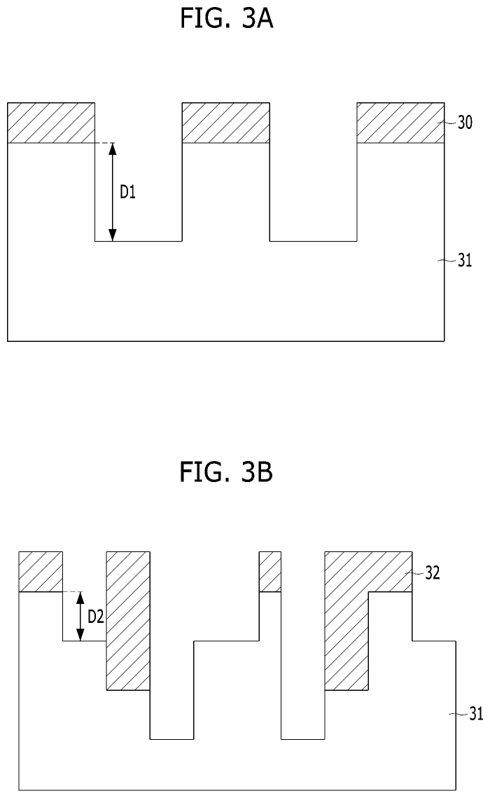

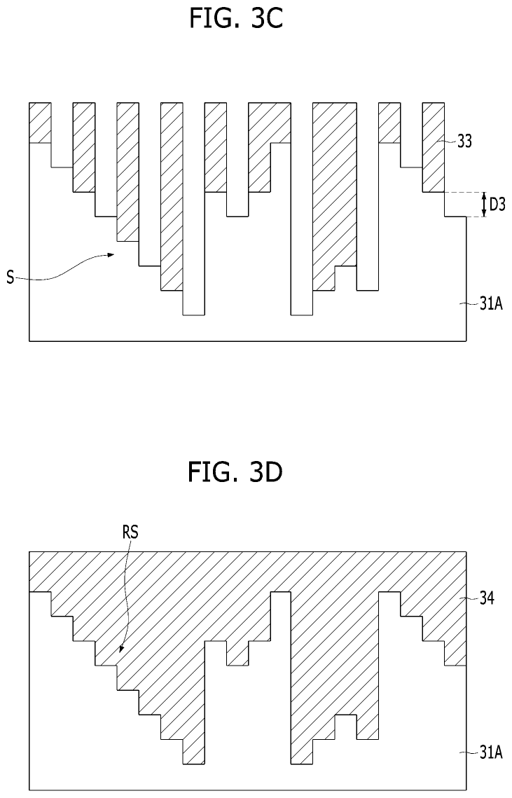

FIGS. 3A to 3D are diagrams illustrating a manufacturing method of a semiconductor device in accordance with an embodiment of the disclosure.

Referring to FIGS. 3A to 3C, a master stamp 31A including a target structure S may be manufactured by etching a substrate 31. The target structure S may include at least one stair. As an example, the target structure S may be formed by repeatedly performing a photolithography process. After a photoresist pattern is formed on the substrate 31, the substrate 31 may be etched using the photoresist pattern as an etching barrier. A photoresist pattern may be formed through photoresist application, exposure, development, and baking. The substrate 31 may be etched using plasma, and the photoresist pattern may be removed after the etching process.

By repeatedly performing the photolithography process, a complex target structure S such as a stair may be implemented. Referring to FIG. 3A, the substrate 31 may be etched to a first depth D1 by using a first mask pattern 30 as an etching barrier. A two-level stepped structure may be formed through a primary etching process. Referring to FIG. 3B, the substrate 31 may be etched to a second depth D2 by using a second mask pattern 32 as an etching barrier. A 4-level stepped structure may be formed through a secondary etching process. The second depth D2 may be different from the first depth D1 and may be smaller than the first depth D1. Referring to FIG. 3C, the substrate 31 may be etched to a third depth D3 by using a third mask pattern 33 as an etching barrier. An 8-level stepped structure may be formed through a tertiary etching process. The third depth D3 may be different from the second depth D2 and may be smaller than the second depth D2. In this way, by performing the etching process n times, the master stamp 31A including a stepped structure having 2ⁿ levels may be manufactured. After forming one mask pattern, a stepped structure may also be formed by repeating a process of shrinking the mask pattern and an etching process using the mask pattern.

Referring to FIG. 3D, a polymer mold 34 may be manufactured using the master stamp 31A. The polymer mold 34 may include a reversed target structure RS. A plurality of duplicate polymer molds 34 may be manufactured using the master stamp 31A.

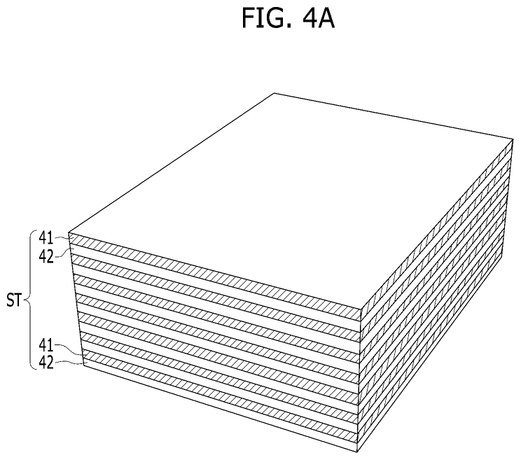

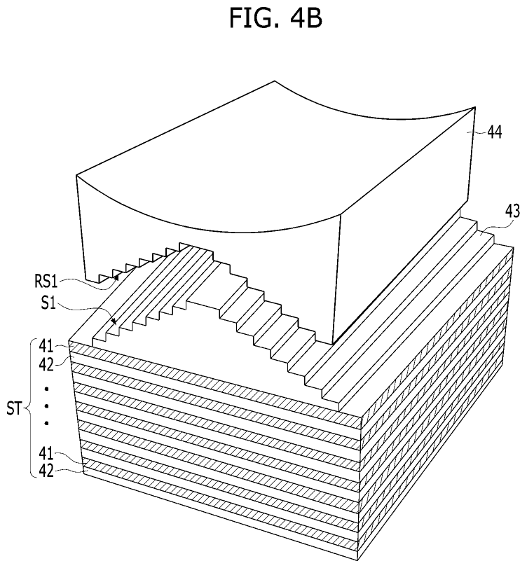

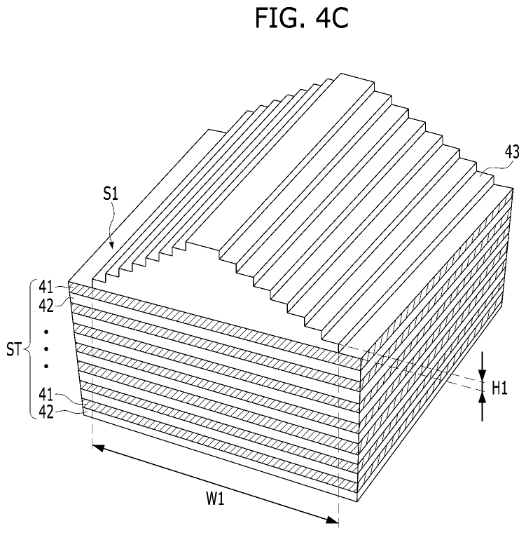

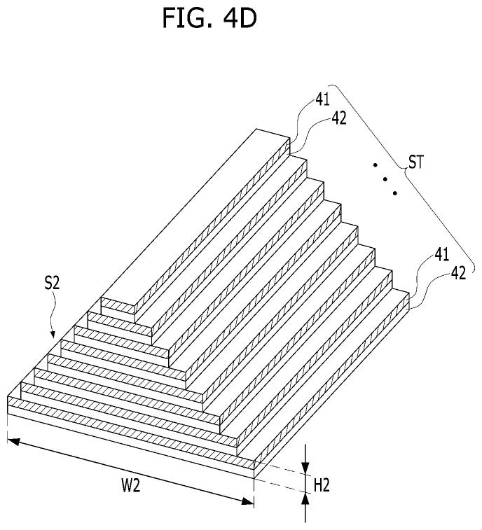

FIGS. 4A to 4D are diagrams illustrating a manufacturing method of a semiconductor device in accordance with an embodiment of the disclosure. Hereinafter, descriptions overlapping with the previously described content will be omitted.

Referring to FIG. 4A, a target layer may be formed. The target layer may be a stack ST, and the stack ST may include first material layers 41 and second material layers 42 that are alternately stacked. The first material layers 41 may be used to form gate lines such as word lines, select lines, and bit lines. The second material layers 42 may be used to insulate stacked gate lines from each other. The first material layers 41 may each include a material having a high etching selectivity with respect to the second material layers 42. As an example, the first material layers 41 may each include a sacrificial material such as nitride and the second material layers 42 may each include an insulating material such as oxide. As an example, the first material layers 41 may each include metal such as polysilicon, tungsten, or molybdenum, and the second material layers 42 may each include an insulating material such as oxide.

Referring to FIG. 4B, an inorganic material-containing polymer mask 43 including a first stepped structure S1 may be formed on the stack ST. As an example, inorganic material-containing resist may be applied on the stack ST. The resist may be formed by dispersing inorganic nanoparticles in a monomer dispersion solution. The monomer may include dipentaerythritol penta/hexaacrylate (DPHA). Subsequently, the inorganic material-containing resist may be pressed with a polymer mold 44. The polymer mold 44 may include a reversed first stepped structure RS1. Subsequently, the inorganic material-containing polymer mask 43 may be cured. As an example, the inorganic material-containing polymer mask 43 may be cured by heat treatment or ultraviolet ray irradiation. A polymer may be formed by polymerization of monomers and inorganic nanoparticles. As a result, the inorganic material-containing polymer mask 43 including the first stepped structure S1 may be formed. Subsequently, the polymer mold 44 may then be removed.

Referring to FIGS. 4C and 4D, the stack ST may be etched using the inorganic material-containing polymer mask 43 as an etching barrier to form a second stepped structure S2 in the stack ST. When the target layer is etched, the inorganic material-containing polymer mask 43 may also be etched. The second stepped structure S2 may be a transfer of the first stepped structure S1 and may have a shape substantially similar to that of the first stepped structure S1. A first step height H1 of the first stepped structure S1 and a second step height H2 of the second stepped structure S2 may be substantially identical to each other or different from each other. A first width W1 of the first stepped structure S1 and a second width W2 of the second stepped structure S2 may be substantially identical to each other or different from each other. As an example, the first height H1 and the second height H2 may be different from each other, and the first width W1 and the second width W2 may be identical to each other. As an example, the first height H1 and the second height H2 may be identical to each other, and the first width W1 and the second width S2 may be identical to each other.

When the stack ST is etched, the inorganic material-containing polymer mask 43 may be used as a hard mask and may have a lower etching rate than the first material layers 41 and the second material layers 42. As an example, the first material layers 41 may each include silicon nitride, and the second material layers 42 may each include silicon oxide. The inorganic material contained in the polymer mask 43 may include at least one of TiO₂, Al₂O₃, ZrO₂, Cr₂O₃, WO₃, ZnO, SnO₂, and Fe₂O₃. When the inorganic material includes metal, the inorganic material-containing polymer mask 43 may have higher hardness than when the inorganic material includes no metal.

According to the manufacturing method described above, the inorganic material-containing polymer mask 43 may be formed by a nano-imprinting method. The inorganic material-containing polymer mask 43 may include the first stepped structure S1. Accordingly, the second stepped structure S2 may be formed in the stack ST using a one-time etching process.

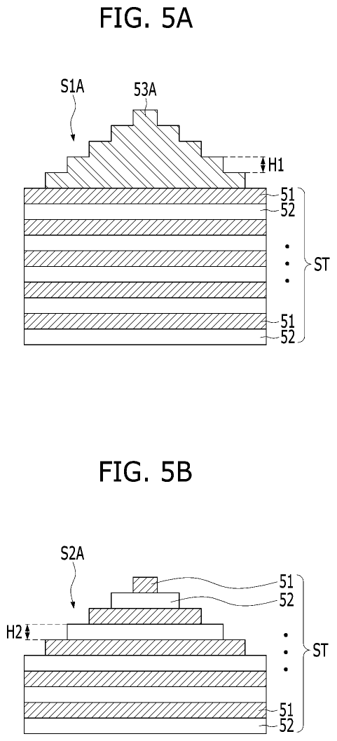

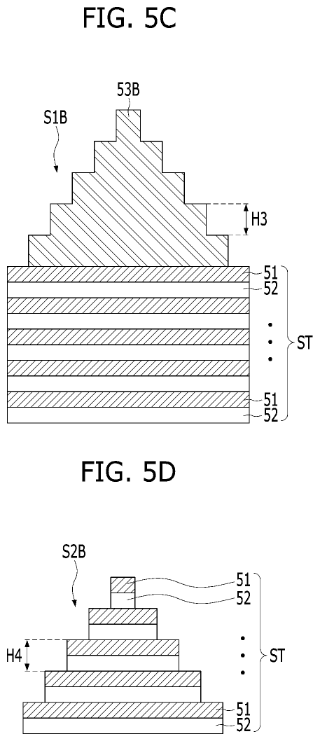

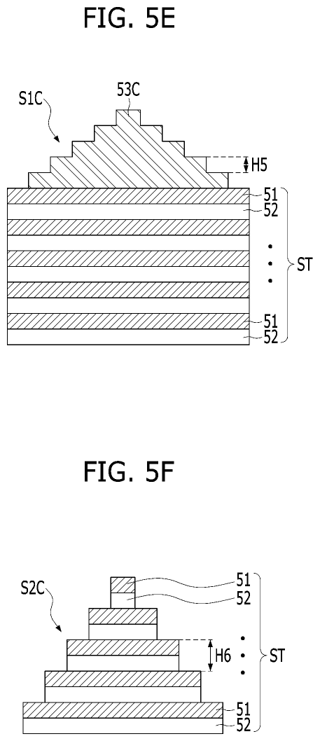

FIGS. 5A to 5F are diagrams illustrating a manufacturing method of a semiconductor device in accordance with an embodiment of the disclosure. Hereinafter, descriptions overlapping with the previously described content will be omitted.

Referring to FIGS. 5A and 5B, a stack ST including first material layers 51 and second material layers 52 that are alternately stacked may be formed. The first material layers 51 may each include a sacrificial material such as nitride, and the second material layers 52 may each include an insulating material such as oxide. The first material layers 51 may each include a material having a high etching selectivity with respect to the second material layers 52. Subsequently, a first inorganic material-containing polymer mask 53A including a first stepped structure S1A may be formed on the stack ST. The first stepped structure S1A may have a first step height H1. Subsequently, the stack ST may be etched using the first inorganic material-containing polymer mask 53A as an etching barrier, and a second stepped structure S2A may be formed in the stack ST. The second stepped structure S2A may have a second step height H2.

The second step height H2 may be adjusted by adjusting the composition of the first inorganic material-containing polymer mask 53A or the first step height H1. As an example, the first step height H1 and the second step height H2 may be substantially identical to each other. The first material layers 51 and the second material layers 52 may be respectively exposed by the second stepped structure S2A.

Referring to FIGS. 5C and 5D, a stack ST including the first material layers 51 and the second material layers 52 that are alternately stacked may be formed. Subsequently, a second inorganic material-containing polymer mask 53B including a first stepped structure S1B may be formed on the stack ST. The first stepped structure S1B may have a third step height H3. Subsequently, the stack ST may be etched using the second inorganic material-containing polymer mask 53B as an etching barrier, and a second stepped structure S2B may be formed in the stack ST. The second stepped structure S2B may have a fourth step height H4.

The fourth step height H4 may be adjusted by adjusting the composition of the second inorganic material-containing polymer mask 53B or the third step height H3. As an example, the third step height H3 and the fourth step height H4 may be substantially identical to each other. The third step height H3 of the second inorganic material-containing polymer mask 53B may be greater than the first step height H1 of the first inorganic material-containing polymer mask 53A. Accordingly, each step in the second stepped structure S2B may include the first material layer 51 and the second material layer 52. Each of the first material layers 51 may be exposed by the second stepped structure S2B.

Referring to FIGS. 5E and 5F, a stack ST including the first material layers 51 and the second material layers 52 that are alternately stacked may be formed. Subsequently, a third inorganic material-containing polymer mask 53C including a first stepped structure S1C may be formed on the stack ST. The first stepped structure S1C may have a fifth step height H5. Subsequently, the stack ST may be etched using the third inorganic material-containing polymer mask 53C as an etching barrier, and a second stepped structure S2C may be formed in the stack ST. The second stepped structure S2C may have a sixth step height H6.

The sixth step height H6 may be adjusted by adjusting the composition of the third inorganic material-containing polymer mask 53C or the fifth step height H5. As an example, the fifth step height H5 and the sixth step height H6 may be different from each other. The third inorganic material-containing polymer mask 53C may have a smaller etching rate than the stack ST, and the fifth height H5 may be smaller than the sixth height H6. Each of the first material layers 51 may be exposed by the second stepped structure S2C.

According to the manufacturing methods described above, by adjusting the step heights H1, H3, and H5 of the inorganic material-containing polymer masks 53A to 53C or by adjusting the compositions of the inorganic material-containing polymer masks 53A to 53C, the shapes of the second stepped structures S2A to S2C formed in the stack ST can be adjusted. Various types of target structures, such as a stepped structure and a reversed pyramid structure, can also be formed in the stack ST through a one-time etching process.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. A manufacturing method of a semiconductor device, the manufacturing method comprising:
forming a stack including first material layers and second material layers that are alternately stacked;
forming, on the stack, an inorganic material-containing polymer mask including a first stepped structure; and
forming a second stepped structure in the stack by etching the stack using the polymer mask as an etching barrier.

2. The manufacturing method of claim 1, wherein the forming of the polymer mask comprises:
applying inorganic material-containing resist on the stack;
pressing the resist with a polymer mold including a reversed stepped structure; and
curing the resist.

3. The manufacturing method of claim 2, wherein the curing of the resist comprises:
forming a polymer by polymerizing monomers and inorganic nanoparticles.

4. The manufacturing method of claim 3, wherein the monomer includes dipentaerythritol penta/hexaacrylate (DPHA).

5. The manufacturing method of claim 1, wherein the inorganic material includes at least one of TiO₂, Al₂O₃, ZrO₂, Cr₂O₃, WO₃, ZnO, SnO₂, and Fe₂O₃.

6. The manufacturing method of claim 1, wherein the polymer mask includes a material having a lower etching rate than the first material layers and the second material layers.

7. The manufacturing method of claim 6, wherein the first material layers each include silicon nitride, the second material layers each include silicon oxide, and the inorganic material includes at least one of TiO₂, Al₂O₃, and ZrO₂.

8. The manufacturing method of claim 1, wherein the polymer mask includes metal.

9. The manufacturing method of claim 1, wherein, the polymer mask is etched when the stack is etched, and the first stepped structure is reproduced in the stack to form the second stepped structure.

10. The manufacturing method of claim 1, wherein a first step height of the first stepped structure and a second step height of the second stepped structure are substantially identical to each other.

11. The manufacturing method of claim 1, wherein a first step height of the first stepped structure and a second step height of the second stepped structure are different from each other.

12. The manufacturing method of claim 1, wherein a first step height of the first stepped structure and a second step height of the second stepped structure are identical to each other or different from each other, and a first width of the first stepped structure and a second width of the second stepped structure are substantially identical to each other.

13. A manufacturing method of a semiconductor device, the manufacturing method comprising:
forming a stack;
applying, on the stack, resist including monomers and inorganic nanoparticles;
pressing the resist with a polymer mold including a reversed target structure;
forming an inorganic material-containing polymer mask including a first target structure by polymerizing the monomers and the inorganic nanoparticles;
removing the polymer mold; and
etching the polymer mask and the stack to form a second target structure in the stack, wherein the first target structure is substantially reproduced to form the second target structure in the stack.

14. The manufacturing method of claim 13, wherein the stack includes first material layers and second material layers that are alternately stacked,
the first material layers each include silicon nitride, the second material layers each include silicon oxide, and
the inorganic material includes at least one of TiO₂, Al₂O₃, and ZrO₂.

15. The manufacturing method of claim 13, wherein the polymer mask includes metal.

16. The manufacturing method of claim 13, wherein the inorganic material includes at least one of TiO₂, Al₂O₃, ZrO₂, Cr₂O₃, WO₃, ZnO, SnO₂, and Fe₂O₃.

17. The manufacturing method of claim 13, wherein a first height of the first target structure and a second height of the second target structure are identical to each other or different from each other, and a first width of the first target structure and a second width of the second target structure are substantially identical to each other.
